(19) United States
(12) Patent Application Publication
(10) Pub. No.: US 2017/0271362 A1
(43) Pub. Date: Sep. 21, 2017

(54) SEMICONDUCTOR MEMORY DEVICE

(71) Applicant: Kabushiki Kaisha Toshiba, Minato-ku (JP)

(72) Inventors: Takeshi SONEHARA, Yokkaichi (JP); Masaru KIDOH, Yokkaichi (JP)

(73) Assignee: Kabushiki Kaisha Toshiba, Minato-ku (JP)

(21) Appl. No.: 15/267,616

(22) Filed: Sep. 16, 2016

Related U.S. Application Data
(60) Provisional application No. 62/308,905, filed on Mar. 16, 2016.

(51) Int. Cl. H01L 27/115; H01L 23/528

(52) U.S. Cl. CPC H01L 27/11582; H01L 27/11565; H01L 27/11556; H01L 27/11519; H01L 23/5283

(57) ABSTRACT

A semiconductor memory device according to an embodiment includes: a first semiconductor layer, a stacked body including a plurality of conductive layers and a plurality of interlayer insulating layers stacked in a first direction above the first semiconductor layer, a second semiconductor layer opposing the plurality of conductive layers, the second semiconductor layer has a longitudinal direction in the first direction, and a memory insulating layer including a charge accumulation layer and positioned between the second semiconductor layer and the plurality of conductive layers. A thickness in the first direction of at least a first conductive layer as one of the plurality of conductive layers is larger than a thickness in the first direction of another one of the plurality of conductive layers, and the first conductive layer is adjacent to the first semiconductor layer via one of the interlayer insulating layers.

### CROSS REFERENCE TO RELATED APPLICATIONS

This application is based on and claims the benefit of priority from prior U.S. Provisional Patent Application No. 62/308,905, filed on Mar. 16, 2016, the entire contents of which are incorporated herein by reference.

Field

Embodiments described herein relate to a semiconductor memory device.

### BACKGROUND

Description of the Related Art

A flash memory that stores data by accumulating a charge in a charge accumulation layer or a floating gate is known. Such a flash memory is connected by a variety of systems such as NAND type or NOR type, and configures a semiconductor memory device. In recent years, increasing of capacitance and raising of integration level of such a semiconductor memory device have been advanced. Moreover, in order to accomplish increasing the capacitance and raising the integration level of such a semiconductor memory device, a semiconductor memory device in which memory cells are arranged three-dimensionally (three-dimensional type semiconductor memory device) has been proposed. In such three-dimensional type semiconductor memory device, various wirings such as word lines and select gate lines are stacked into multiple layers in a stacking direction, and are drawn out to outside via contacts.

### BRIEF DESCRIPTION OF THE DRAWINGS

FIG. 1 is a block diagram of a nonvolatile semiconductor memory device according to a first embodiment.

FIG. 2 is a circuit diagram showing a configuration of part of the nonvolatile semiconductor memory device according to the first embodiment.

FIG. 3 is a perspective view showing a configuration of part of the nonvolatile semiconductor memory device according to the first embodiment.

FIG. 4 is a perspective view showing a configuration of part of the nonvolatile semiconductor memory device according to the first embodiment.

FIG. 5 is a cross-sectional view showing a configuration of part of the nonvolatile semiconductor memory device according to the first embodiment.

FIG. 6 is a cross-sectional view showing a configuration of part of the nonvolatile semiconductor memory device according to the first embodiment.

FIGS. 7 to 15 are process charts showing a method of manufacturing the nonvolatile semiconductor memory device according to the first embodiment.

FIG. 16 is a cross-sectional view showing a configuration of part of the nonvolatile semiconductor memory device according to a second embodiment.

### DETAILED DESCRIPTION

A semiconductor memory device according to one embodiment includes a first semiconductor layer, a stacked body, a second semiconductor layer, and a memory insulating layer. The stacked body includes a plurality of conductive layers and a plurality of interlayer insulating layers that are stacked in a first direction above the first semiconductor layer. The second semiconductor layer is opposed to the plurality of conductive layers and has their longitudinal direction in a first direction. The memory insulating layer includes a charge accumulation layer and is positioned between the second semiconductor layer and the plurality of conductive layers. A thickness in the first direction of at least a first conductive layer as one of the plurality of conductive layers is larger than a thickness in the first direction of another one of the plurality of conductive layers, and the first conductive layer is adjacent to the first semiconductor layer via one of the interlayer insulating layers.

Next, a non-volatile semiconductor memory device according to embodiments will be described in detail with reference to the drawings. Note that these embodiments are merely examples, and are not shown with the intention of limiting the present invention.

For example, a non-volatile semiconductor memory device described below has a structure in which a memory string extends in a straight line in a direction intersecting with the substrate. A similar structure is also applicable to the structure having a U shaped memory string that is folded to the opposite side in the middle. Moreover, each of the drawings of the nonvolatile semiconductor memory devices employed in the embodiments below is schematic, and thicknesses, widths, ratios, and so on, of layers are different from those of the actual nonvolatile semiconductor memory devices.

The nonvolatile semiconductor memory devices described below relates to a nonvolatile semiconductor memory device having a structure in which a plurality of MONOS (Metal-Oxide-Nitride-Oxide-Semiconductor) type memory cells (transistors) are provided in a direction intersecting with the substrate, each of the MONOS type memory cells including: a semiconductor layer acting as a channel provided in a column shape intersecting with a substrate; and a control gate electrode made of metal and provided on a side surface of the semiconductor layer via a charge accumulation layer. However, this is also not intended to limit the present invention, and the present invention may be applied also to a memory cell of another form of charge accumulation layer, for example, a SONOS (Semiconductor-Oxide-Nitride-Oxide-Semiconductor) type memory cell, or a floating gate type memory cell.

### First Embodiment

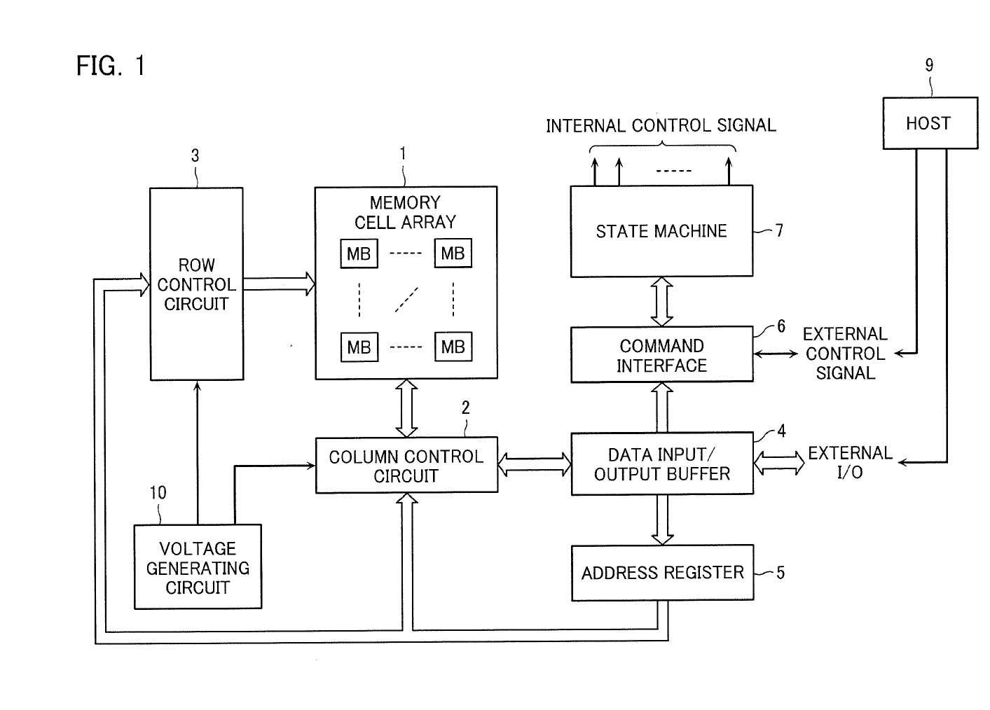

FIG. 1 is a block diagram of a nonvolatile semiconductor memory device according to a first embodiment. The nonvolatile semiconductor memory device stores user data inputted from an external host 9, in a certain address in a memory cell array 1. In addition, the nonvolatile semiconductor memory device reads the user data from a certain address in the memory cell array 1, and outputs the user data to the external host 9.

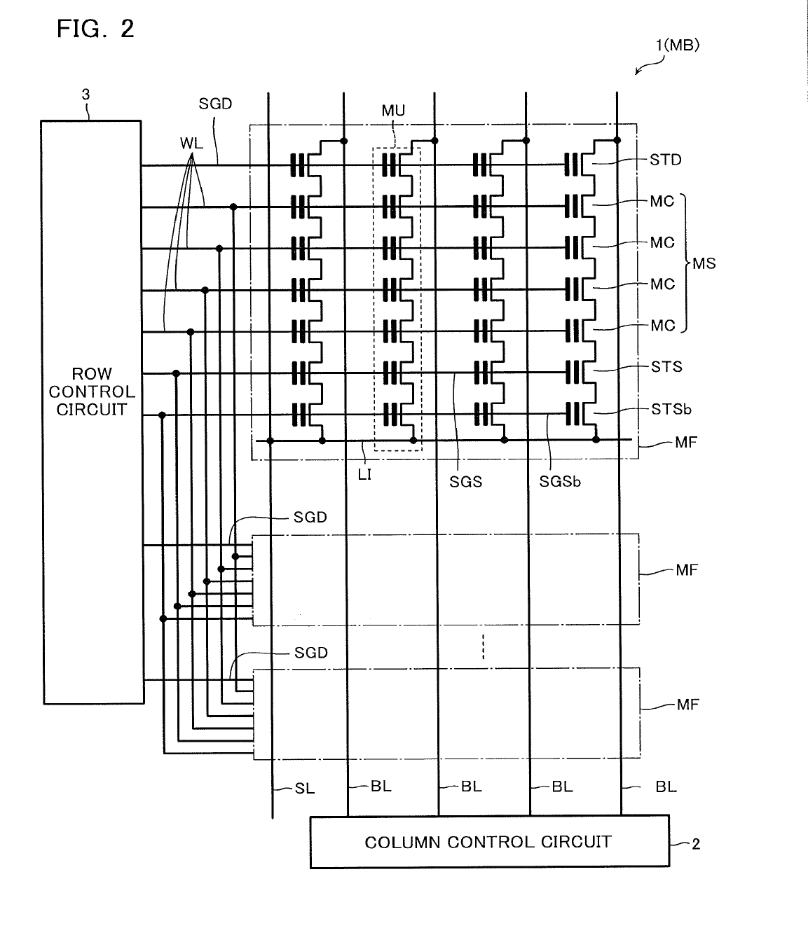

The nonvolatile semiconductor memory device includes the memory cell array 1 that stores the user data. The memory cell array 1 includes a plurality of memory blocks MB. As will be described later with reference to FIG. 2, these memory blocks MB each include: a plurality of memory cells MC; and bit lines BL and word lines WL connected to these memory cells MC.

The nonvolatile semiconductor memory device includes a column control circuit 2 provided in a periphery of the memory cell array 1. When writing of user data is performed, the column control circuit 2 transfers a voltage generated by a voltage generating circuit 10 to a desired bit line BL according to inputted user data. Moreover, the column control circuit 2 includes an unillustrated sense amplifier. When user data is read, the sense amplifier detects a voltage or potential of a certain bit line BL.

The nonvolatile semiconductor memory device includes a row control circuit 3 disposed in a periphery of the memory cell array 1. The row control circuit 3 transfers a voltage generated by the voltage generating circuit 10 to a desired word line WL and the like, according to an inputted address data.

The nonvolatile semiconductor memory device includes an address register 5 that provides the address data to the column control circuit 2 and the row control circuit 3. The address register 5 stores the address data inputted from a data input/output buffer 4.

The nonvolatile semiconductor memory device includes the voltage generating circuit 10 that provides the voltage to the memory cell array 1 via the column control circuit 2 and the row control circuit 3. The voltage generating circuit 10 generates and outputs a voltage of a certain magnitude at certain timing, based on an internal control signal inputted from a state machine 7.

The nonvolatile semiconductor memory device includes the state machine 7 that inputs the internal control signal to the voltage generating circuit 10, and the like. The state machine 7 receives command data from the host 9, via a command interface 6, and performs management of read, write, erase, input/output of data, and so on.

The nonvolatile semiconductor memory device includes the data input/output buffer 4 that is connected to the external host 9 via the I/O line. The data input/output buffer 4 receives write data from the external host 9, and transfers the write data to the column control circuit 2. Moreover, the data input/output buffer 4 receives the command data from the external host 9, and transfers the command data to the command interface 6. In addition, the data input/output buffer 4 receives the address data from the external host 9, and transfers the address data to the address register 5. Furthermore, the data input/output buffer 4 receives the read data from the column control circuit 2, and transfers the read data to the external host 9.

The nonvolatile semiconductor memory device includes the command interface 6 that receives an external control signal from the external host 9. The command interface 6 determines whether the data inputted to the data input/output buffer 4 is the write data, the command data, or the address data, based on the external control signal inputted from the external host 9, and controls the data input/output buffer 4. Moreover, the command interface 6 transfers the command data received from the data input/output buffer 4 to the state machine 7.

Note that, the column control circuit 2, the row control circuit 3, the state machine 7, the voltage generating circuit 10, and so on, configure a control circuit that controls the memory cell array 1.

Next, with reference to FIG. 2, a circuit configuration of part of the memory cell array 1 according to the present embodiment will be described. FIG. 2 is an equivalent circuit diagram showing the configuration of the memory block MB configuring the memory cell array 1.

The memory block MB includes the plurality of memory cells MC. Each of the memory cells MC stores data of one bit or a plurality of bits that configures the user data described above. Moreover, in the memory block MB shown in FIG. 2, a certain drain side select gate line SGD and a certain word line WL are selected by the row control circuit 3. This allows a certain number of memory cells MC to be selected. These selected memory cells MC are each connected to the bit lines BL. Currents or voltages of these bit lines BL are different in volume depending on the data stored in the memory cells MC. The column control circuit 2 determines the data stored in the plurality of memory cells MC by detecting the current or the voltage of the bit line BL, and output the data as the user data.

Each of the memory blocks MB includes a plurality of memory fingers MF. The plurality of bit lines BL and a source line SL are commonly connected to these pluralities of memory fingers MF. Each of the memory fingers MF is connected to the column control circuit 2 via the bit lines BL, and is connected to an unillustrated source line driver via the source line SL.

The memory finger MF configures a plurality of memory units MU. The memory unit MU has one end connected to the bit line BL, and has the other end connected to the source line SL via a source contact LI. The memory units MU included in one memory finger MF are all connected to different bit lines BL.

The memory unit MU includes the plurality of the memory cells MC connected in series. As described below, the memory cell MC includes a semiconductor layer that functions as a channel, a charge accumulation layer, and a control gate electrode. Furthermore, the memory cell MC accumulates a charge in the charge accumulation layer based on a voltage applied to the control gate electrode, and change a control gate voltage (a threshold voltage) to set the channel into a conductive state. Hereafter, the plurality of memory cells MC connected in series will be called a “memory string MS”. The row control circuit 3 transfers a voltage to a certain word line WL, thereby transferring this voltage to a control gate electrode of a certain memory cell MC in the memory string MS.

Control gates of the plurality of the memory cells MC included in different memory strings MS are commonly connected to a word line WL, respectively. The plurality of memory cells MC are connected to the row control circuit 3 via the word line WL. Moreover, in the example shown in FIG. 2, the word lines WL are independently provided for each of the memory cells MC included in the memory unit MU, and are commonly provided for all of the memory units MU included in one memory block MB.

The memory unit MU includes a drain side select gate transistor STD connected between the memory string MS and the bit line BL. The drain side select, gate line SGD is connected to a control gate of the drain side select gate transistor STD. The drain side select gate line SGD is connected to the row control circuit 3, and selectively connects the memory string MS and the bit line BL based on an inputted signal. Moreover, in the example shown in FIG. 2, the drain side select gate line SGD is independently provided for each of the memory fingers MF, and is commonly connected to the control gates of all of the drain side select gate transistors STD in the memory finger MF. The row control circuit 3 selectively connects all of the memory strings MS in a certain memory finger MF to the bit lines BL by selecting a certain drain side select gate line SGD.

Moreover, the memory unit MU includes a source side select gate transistor STS and a lowermost layer source side select gate transistor STSb connected between the memory string MS and the source contact LI. The lowermost layer source side select gate transistor STSb is connected to a lower end of the memory unit MU. The source side select gate transistor STS is connected between the lowermost layer source side select gate transistor STSb and the memory cell MC.

A source side select gate line SGS is connected to a control gate of the source side select gate transistor STS. In addition, a lowermost layer source side select gate line SGSb is connected to a control gate of the lowermost layer source side select gate transistor STSb. Moreover, in the example shown in FIG. 2, the source side select gate line SGS is commonly connected to all of the source side select gate transistors STS in the memory blocks MB. Similarly, the lowermost layer source side select gate line SGSb is commonly connected to all of the lowermost layer source side select gate transistors STSb in the memory block MB. The row control circuit 3 connects all of the memory strings MS in the memory block MB to the source line SL.

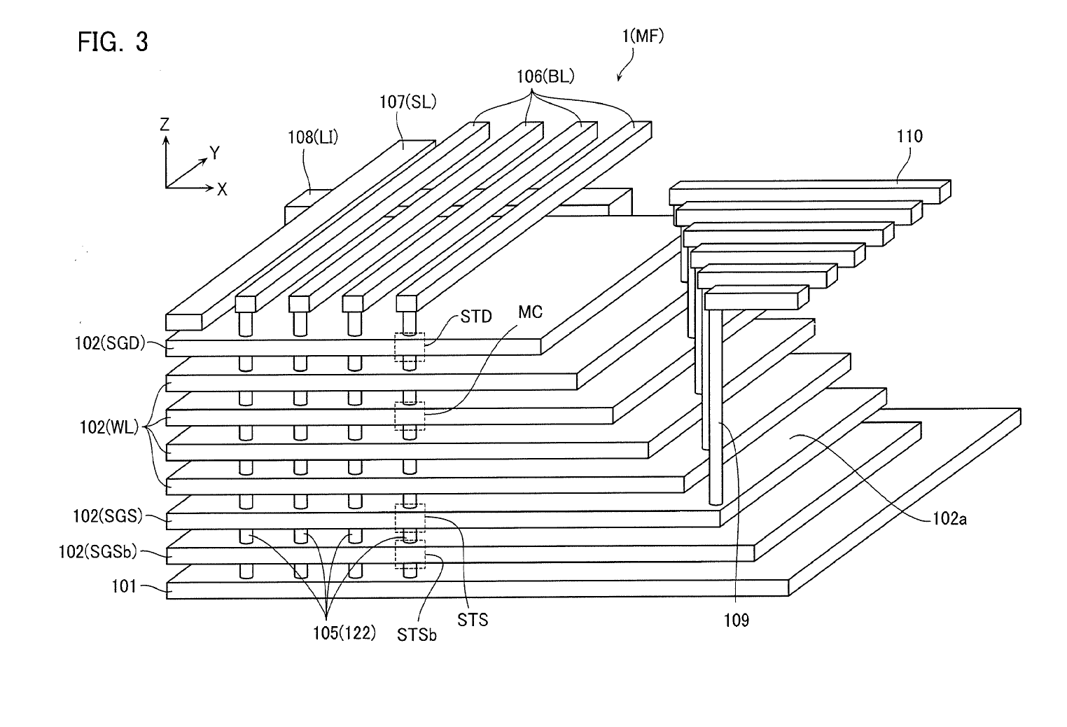

Next, with reference to FIG. 3, a schematic configuration of the memory cell array 1 will be described. FIG. 3 is a schematic perspective view showing a configuration of part of the memory finger MF. Note that in FIG. 3, part of the configuration is omitted. Moreover, the configuration shown in FIG. 3 is merely an example, and a specific configuration may be appropriately changed.

The memory finger MF includes a substrate 101 and a plurality of conductive layers 102 stacked in a Z direction above the substrate 101. In addition, the memory finger MF includes a plurality of memory columnar bodies 105 extending in the Z direction. An intersection of the conductive layer 102 and the memory columnar body 105 functions as the lowermost layer source side select gate transistor STSb, the source side select gate transistor STS, the memory cell MC, or the drain side select gate transistor STD. The conductive layers 102 are formed of conductive layers such as tungsten (W), polysilicon, for example, and function as the word lines WL, the control gate electrode of the memory cell MC, the source side select gate line SGS, the control gate electrode of the source side select gate transistor STS, the drain side select gate line SGD, the control gate electrode of the drain side select gate transistor STD, the lowermost layer source side select gate line SGSb, or the control gate electrode of the lowermost layer source side select gate transistor STSb.

End portions in an X direction of the plurality of conductive layers 102 are formed in steps. That is, the conductive layers 102 include contact portions 102a. The contact portion 102a is not opposed to a lower surface of a conductive layer 102 which is positioned on an upper layer of the contact portion 102a. In addition, the conductive layer 102 is connected to a via contact wiring 109 (being merely said as a “contact 109” in the following). Moreover, a wiring 110 is provided above the contact 109. Note that the contact 109 and the wiring 110 are formed of conductive layers such as tungsten.

The memory finger MF includes a conductive layer 108. The conductive layer 108 opposes a side surfaces in a Y direction of the plurality of conductive layers 102, and has tabular shape extending in the X direction and the Z direction. A lower end of the conductive layer 108 contacts the substrate 101. The conductive layer 108 is formed of a conductive layer such as tungsten (W), for example, and functions as the source contact LI.

The memory finger MF includes a plurality of conductive layers 106 and a conductive layer 107 which extend in the Y direction and are arranged in the X direction. The plurality of conductive layers 106 and the conductive layer 107 are positioned above the plurality of conductive layers 102 and the plurality of memory columnar bodies 105. The memory columnar bodies 105 are connected to a lower surface of the conductive layers 106, respectively. The conductive layers 106 are formed of conductive layers such as tungsten (W), for example, and function as the bit lines BL. Moreover, the conductive layer 108 is connected to a lower surface of the conductive layer 107. The conductive layer 107 is formed of a conductive layer such as tungsten (W), for example, and functions as the source line SL.

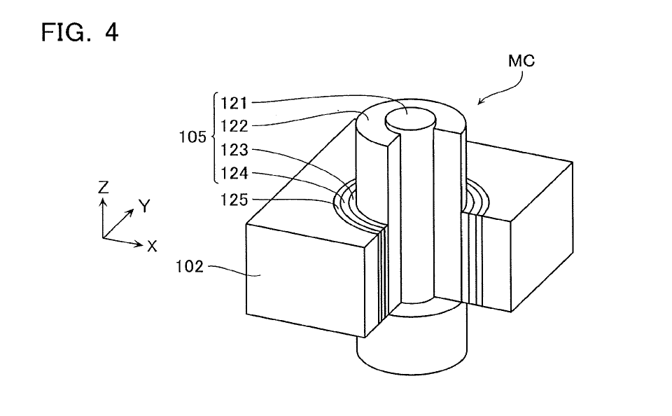

Next, a schematic configuration of the memory cell MC will be described with reference to FIG. 4. FIG. 4 is a schematic perspective view showing a configuration of the memory cell MC. Note that in FIG. 4, part of configuration is omitted.

The memory cell MC is provided at an intersection of the conductive layer 102 and the memory columnar body 105. The memory columnar body 105 includes a core insulating layer 121, a semiconductor layer 122 stacked on a sidewall of the core insulation layer 121, a tunnel insulating layer 123 and a charge accumulation layer 124. Furthermore, a block insulating layer 125 is provided between the memory columnar body 105 and the conductive layer 102.

The core insulating layer 121 is formed of an insulating layer such as silicon oxide (SiO₂), for example. The semiconductor layer 122 is formed of a semiconductor layer such as polysilicon, for example, and functions as a channel of the memory cell MC. The tunnel insulating layer 123 is formed of an insulating layer such as silicon oxide (SiO₂), for example. The charge accumulation layer 124 is formed of an insulating layer capable of accumulating a charge, such as silicon nitride (SiN), for example. The block insulating layer 125 is formed of an insulating layer such as silicon oxide (SiO₂), for example. Note that in FIG. 4, an unillustrated high dielectric film formed of alumina (Al₂O₃), for example, may be interposed between the block insulating layer 125 and the conductive layer 102. The following describes an example in which the high dielectric film is absent, but it is needless to say that the example does not limit the contents of this embodiment.

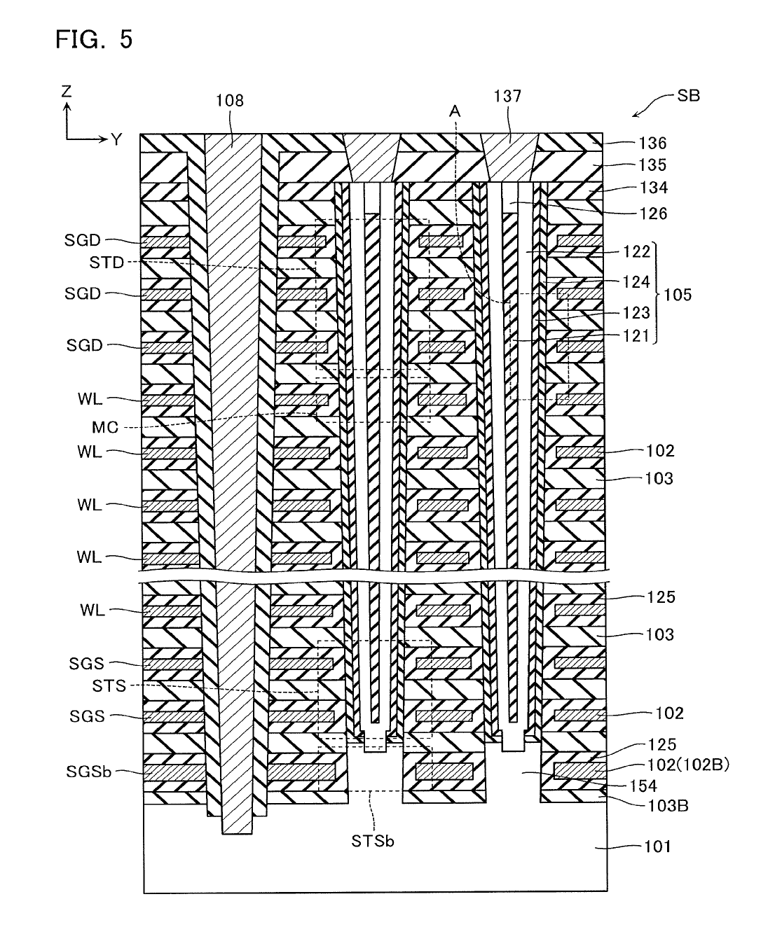

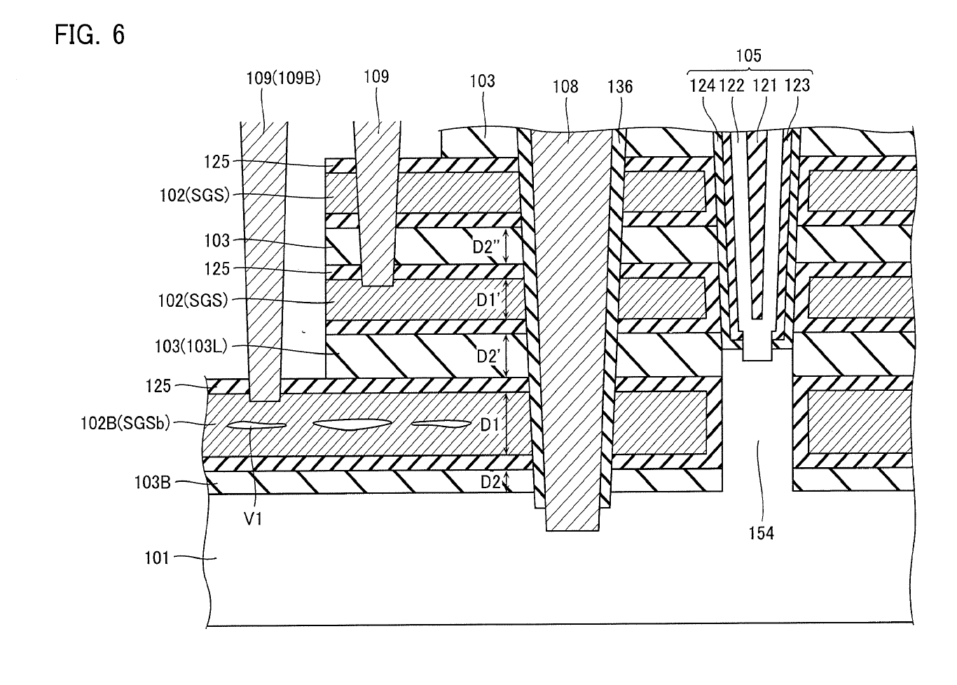

Next, the nonvolatile semiconductor memory device according to the embodiment will be described in more detail with reference to FIGS. 5 and 6. FIG. 5 is a cross-sectional view showing a configuration of part of the nonvolatile semiconductor memory device. FIG. 6 is an enlarged cross-sectional view showing apart of the control gate (the select gate line SGSb) of the source side select gate transistor STSb shown in FIG. 5.

The nonvolatile semiconductor memory device according to the embodiment includes the substrate 101, a stacked body SB disposed above the substrate 101, the memory columnar bodies 105 and the conductive layer 108. The stacked body SB includes the plurality of conductive layers 102 stacked above the substrate 101. These plurality of conductive layers 102 function as the control gate of the memory cell MC, the word line WL, and the select gate lines of the select gate transistors STD, STS and STSb. The memory columnar body 105 includes the semiconductor layer 122 extending in the Z direction perpendicular to the substrate 101. The semiconductor layer 122 functions as a channel of the memory cell MC and so on. The conductive layer 108 functions as the source contact LI.

Next, the stacked body SB will be described. The stacked body SB includes the plurality of conductive layers 102 and a plurality of interlayer insulating layers 103 disposed alternatively above the substrate 101. In addition, the stacked body SB includes the block insulating layers 125 covering an upper surface, a lower surface and a side surface of the conductive layer 102. The conductive layers 102 are formed of conductive material such as tungsten (W), for example, and function as the control gate of the memory cell MC or the word line WL and so on. Moreover, the interlayer insulating layers 103 and the block insulating layers 125 are formed of insulation materials, such as silicon oxide (SiO₂), for example.

Note that, insulating layers 134, 135 and 136 are stacked in this order on an uppermost layer of the interlayer insulating layer 103. In addition, bit line contacts 137 are disposed through these insulating layers 134, 135 and 136, and the bit line contacts 137 reach the memory columnar body 105. The bit line contacts 137 are connected to unillustrated bit lines BL (conductive layer 106) at upper ends thereof.

A film thickness D1 of a conductive layer 102B included in the conductive layers 102 is larger than a film thickness D1′ in the Z direction of another one of the conductive layers 102 (with reference to FIG. 6). The conductive layer 102B is positioned at a lowermost layer of the stacked body SB and functions as the lowermost layer source side select gate line SGSb.

In addition, an interlayer insulating layer 103B is positioned between the conductive layer 102B and the substrate 101. Accordingly, the conductive layer 102B is adjacent to the substrate 101 via the interlayer insulating layer 103B. A film thickness D2 in the Z direction of the interlayer insulating layer 103B is smaller than a film thickness in the Z direction of an interlayer insulating layer 103L positioned at an upper layer of the interlayer insulating layer 103B (with reference to FIG. 6). Because of this, an inversion layer (a channel) is formed along a surface of the substrate 101 when a certain voltage is applied to the lowermost layer source side select gate line SGSb (the conductive layer 102B). Consequently, a sufficient cell current can be flown via the memory unit MU, the substrate 101 and the source contact LI. Note that a film thickness D2′ of the interlayer insulating layer 103L positioned at an upper end of the semiconductor layer 154 is larger than a film thickness D2″ of another one of the interlayer insulating layers 103 positioned at a further upper layer of the interlayer insulating layer 103L (D2′>D2″). The film thickness D2 of the interlayer insulating layer 103B is further smaller than the film thickness D2″ of another one of the interlayer insulating layers 103 (D2″>D2). Note that, here, the upper end of the semiconductor layer 154 means a position in the Z direction. Specifically, the upper end of the semiconductor layer 154 is identified as a boundary between monocrystalline silicon configuring the semiconductor layer 154 formed by epitaxial growth and polysilicon configuring the semiconductor layer 122. As described above, the film thickness D1 in the Z direction of the conductive layer 102B that functions as the lowermost source side select gate line SGSb is set larger than the film thickness D1′ in the Z direction of another one of the conductive layers 102. The reason is as follows. Namely, the interlayer insulating layer 103B positioned at a lower layer of the conductive layer 102 has the film thickness D2 in the Z direction smaller than the film thickness D2′ of another one of the interlayer insulating layers 103. In addition, since the conductive layer 102B is positioned at the lowermost layer of the stacked body SB, the conductive layer 102B is easily damaged by a gas used in a CVD method for embedding the conductive layers or a gas emitted from the material itself, when a method of manufacturing described below is adopted. Furthermore, as shown in FIG. 6, voids V1 are easily generated inside the conductive layer 102B. Therefore, when the contact 109 (109B) that extends to the conductive layer 102B from an upper layer of the stacked body SB is formed, there is a possibility that the contact 109B penetrates the conductive layer 102B, and furthermore, penetrates the interlayer insulating layer 103B which has small film thickness and ends up reaching the substrate 101. When the contact 109B penetrates the conductive layer 102B and the interlayer insulating layer 103B and reaches the substrate 101, in this way, the lowermost layer source side select gate transistor STSb cannot function as a switching element. The lowermost layer source side select gate line SGSb is usually commonly connected to all memory strings MS in one memory block MB. In this case, when the contact 109B reaches the substrate 101 as described above, one memory block MB becomes unusable, as a whole. Therefore, in the present embodiment, short-circuit between the lowermost source side select gate line SGSb and the substrate 101 is prevented by enlarging the film thickness of the lowermost layer conductive layer 102B compared with the film thickness of another one of the conductive layers 102. In other words, a process margin of the contact 109 can be increased, and a processing cost can be reduced.

Note that in view of preventing penetration of the contact 109, enlarging of film thicknesses of the conductive layers 102 configuring the word lines WL or the drain side select gate line SGD may be considered. However, when the film thicknesses of all of the conductive layers 102 included in the stacked body SB are enlarged, the whole thickness in the Z direction of the stacked body SB increases, thus a processing of memory holes MH becomes difficult. Therefore, it is preferable to enlarge only the film thickness of the lowermost layer conductive layer 102B compared with other ones of the conductive layers 102.

The memory columnar body 105 includes a semiconductor layer 154. The semiconductor layer 154 is integrally formed with the substrate 101 and extends in the Z direction. The semiconductor layer 154 is a semiconductor layer formed on the substrate 101 by epitaxial growth by which the crystal plane of the semiconductor layer 154 is aligned to that of the substrate 101 below the semiconductor layer 154. When the substrate 101 is silicon substrate, the semiconductor layer 154 is formed of monocrystalline silicon and so on, for example, and functions as a channel of the lowermost layer source side select gate transistor SGSb. A lower end of the semiconductor layer 122 is connected to an upper end of the semiconductor layer 154.

### [Method of Manufacturing]

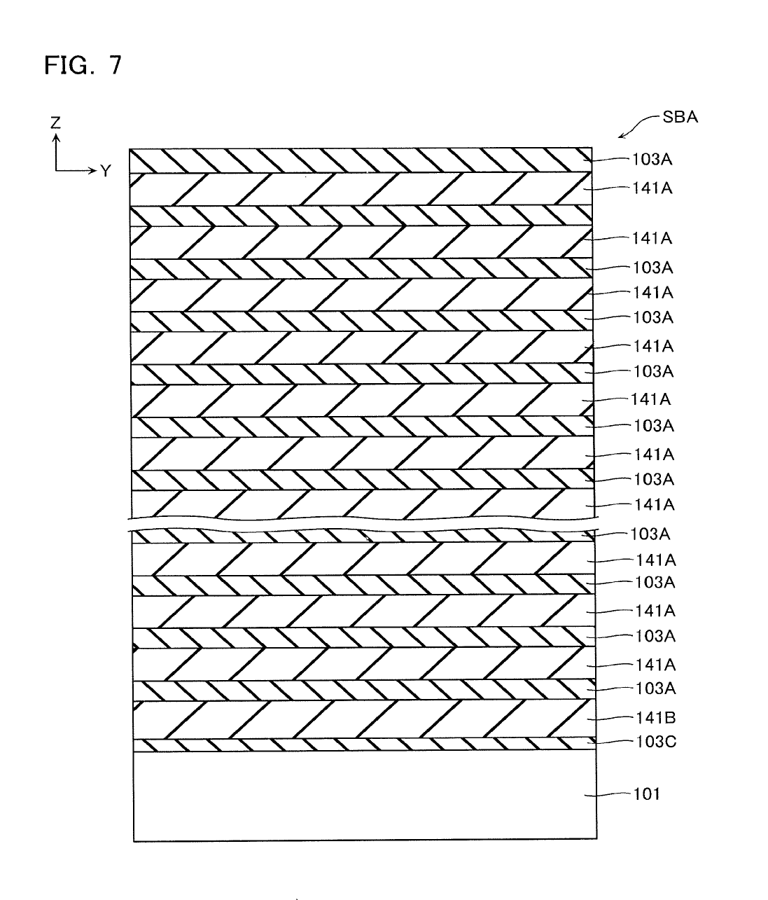

Next, a method of manufacturing a nonvolatile semiconductor memory device according to the embodiment will be described with reference to FIGS. 7 to 15.

As shown in FIG. 7, after an interlayer insulating layer 103C and a sacrifice layer 141B are stacked on the substrate 101, interlayer insulating layers 103A and sacrifice layers 141A are stacked alternately above the interlayer insulating layer 103C and the sacrifice layer 141B, to form a stacked body SBA. The interlayer insulating layer 103C is a layer that will be the interlayer insulating layer 103B described above. The interlayer insulating layers 103A are layers that will be the interlayer insulating layers 103. Therefore, the interlayer insulating layer 103C is formed so as to make a thickness thereof smaller than a thickness of the interlayer insulating layer 103A. The sacrifice layers 141B and 141A are films removed by etching in a process described below. The conductive layers 102B and 102 are respectively formed in cavities generated by removing of the sacrifice layers 141B and 141A. Thus, a film thickness in the Z direction of the sacrifice layer 141B is enlarged compared with a film thickness in the Z direction of the sacrifice layer 141A. The interlayer insulating layer 103C and the interlayer insulating layers 103A are formed of silicone oxide (SiO₂), for example. The sacrifice layers 141A and 141B are formed of silicon nitride (SiN), for example.

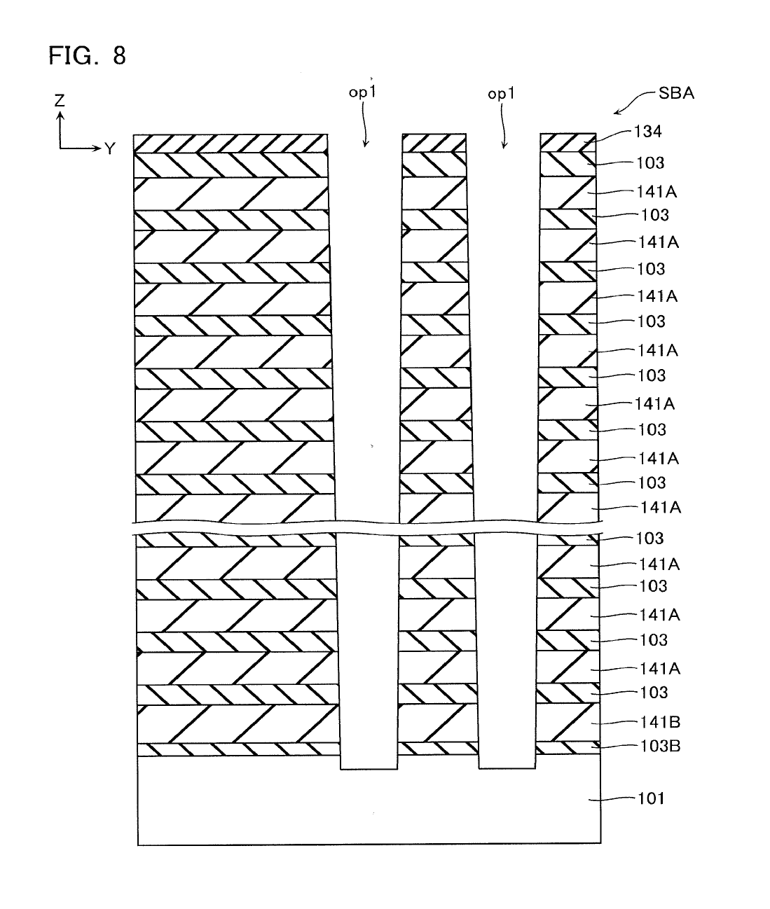

Next, as shown in FIG. 8, openings op1 are formed in the stacked body SBA. The memory units MU mentioned above is formed in the openings op1. After forming the insulating layer 134 on an upper surface of the stacked body SBA, anisotropic etching such as RIE (Reactive Ion Etching) using the insulating layer 134 as a mask is performed and the openings op1 are formed at the stacked body SBA. The openings op1 are formed so as to penetrate the interlayer insulating layers 103 and 103B and the sacrifice layers 141A and 141B, and reach the substrate 101.

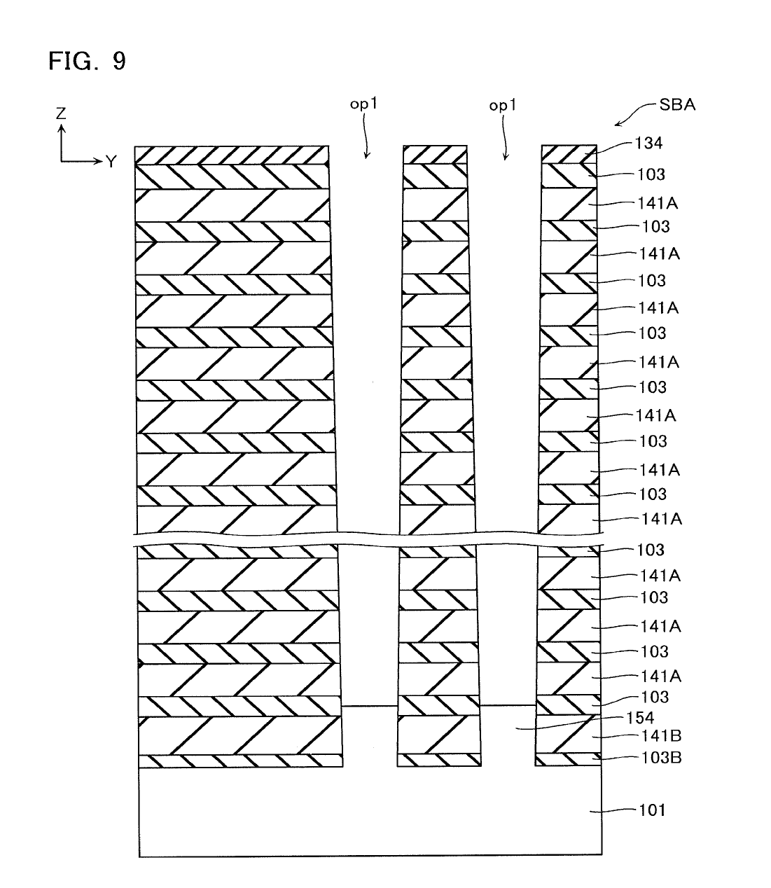

Next, as shown in FIG. 9, a crystal growth method such as epitaxial growth is executed, thus the semiconductor layers 154 are formed at bottom parts of the openings op1. The semiconductor layers 154 are formed of monocrystalline silicon integrally formed with the substrate 101, for example. As shown in FIG. 9, the crystal growth method here is executed until surfaces of the semiconductor layers 154 reach the lowermost layer sacrifice layer 103, for example.

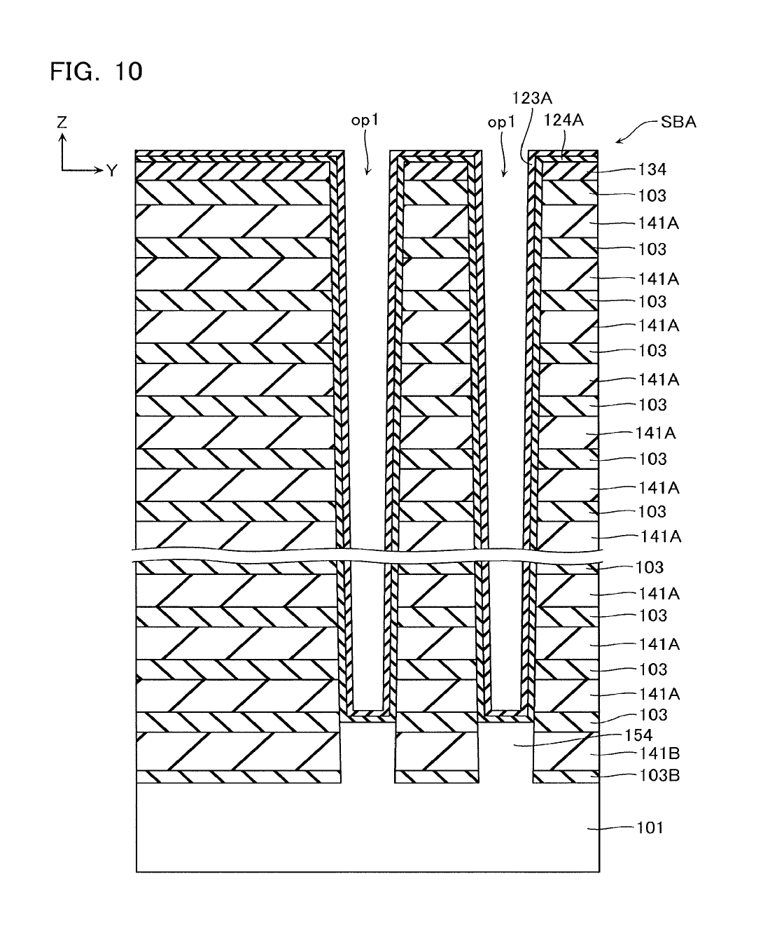

Next, as shown in FIG. 10, a charge accumulation layer 124A and an insulating layer 123A are formed on an inner wall and a bottom part of the openings op1 and on an upper surface of the stacked body SBA. The charge accumulation layer 124A will be the charge accumulation layer 124. The insulating layer 123A, will be the tunnel insulating layer 123. The charge accumulation layer 124A is formed of silicon nitride (SiN), for example. The insulating layer 123A is formed of silicon oxide (SiO₂), for example.

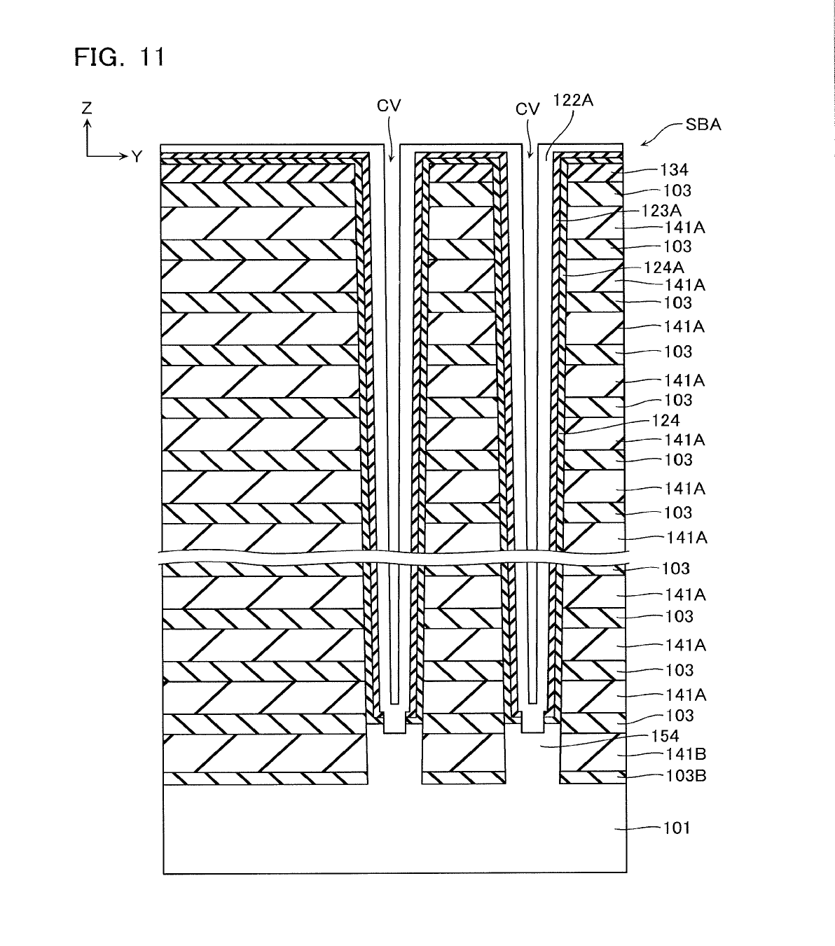

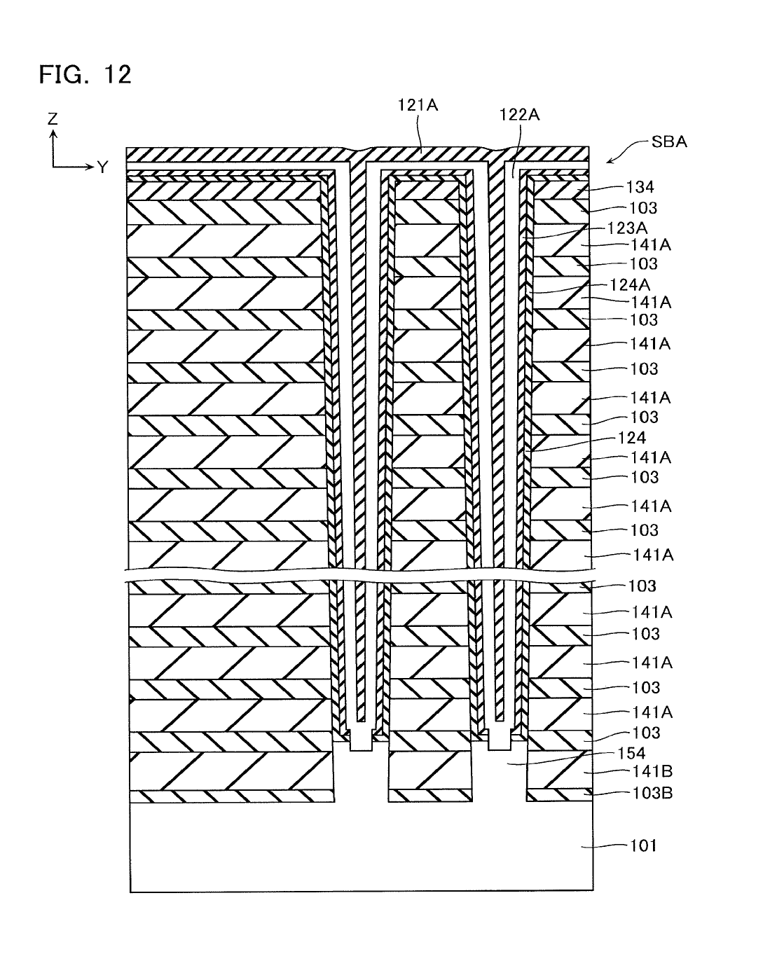

Next, as shown in FIG. 11, after the charge accumulation layer 124A and the insulating layer 123A accumulated on the bottom part of the openings op1 are removed by RIE, a semiconductor layer 122A is formed on an inner wall and a bottom part of the openings op1 and on an upper surface of the stacked body SBA. The semiconductor layer 122A is a material of the semiconductor layer 122 mentioned above, and is formed of amorphous silicon, for example. Note that, the semiconductor layer 122A is deposited while leaving a cavity CV inside thereof. Furthermore, as shown in FIG. 12, a core insulating layer 121A is embedded into the openings op1 so as to fill the cavity CV. Then, CMP (Chemical Mechanical Polishing) is executed using the insulating layer 134 and so on as a stopper for planarization. Furthermore, heat treating is executed to change crystalline structure of the semiconductor layer 122 in an amorphous state to a polycrystalline structure.

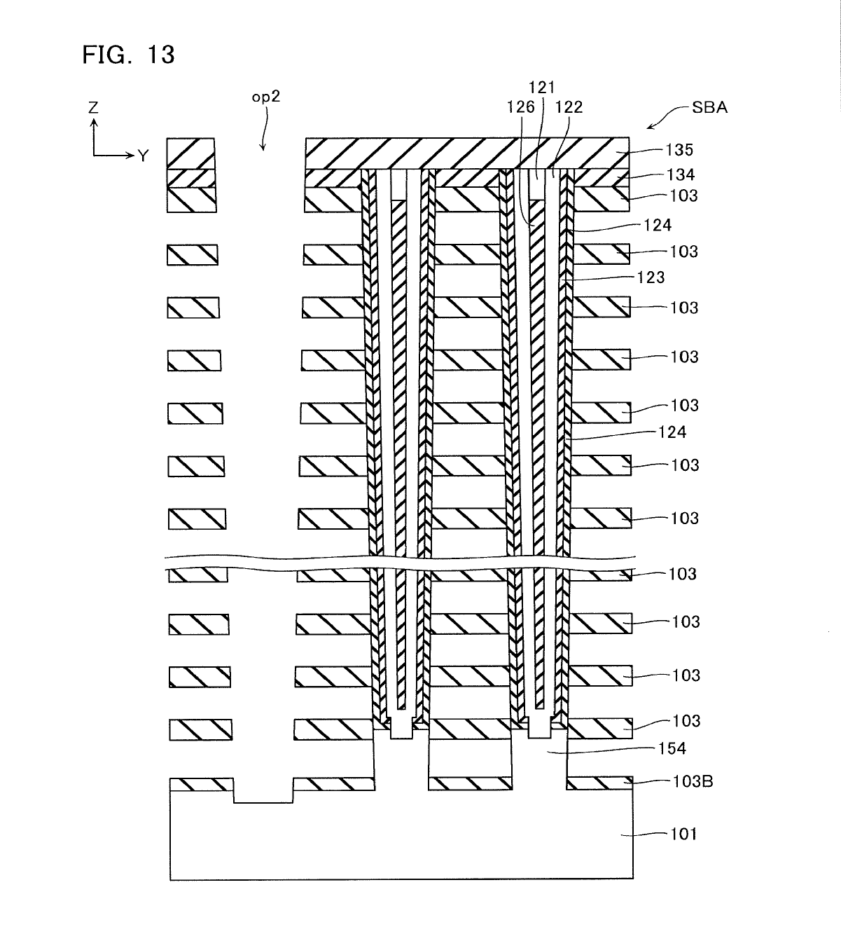

Moreover, as shown in FIG. 13, an insulating layer 135 is formed on the stacked body SBA. Then, anisotropic etching such as RIE is executed while using the insulating layer 135 as a mask, and a trench op2 penetrating the stacked body SBA is formed. After that, a wet etching using a phosphoric acid, for example, is executed and the sacrifice layers 141A and 141B are removed, a state of the stacked body SBA illustrated in FIG. 13 is obtained.

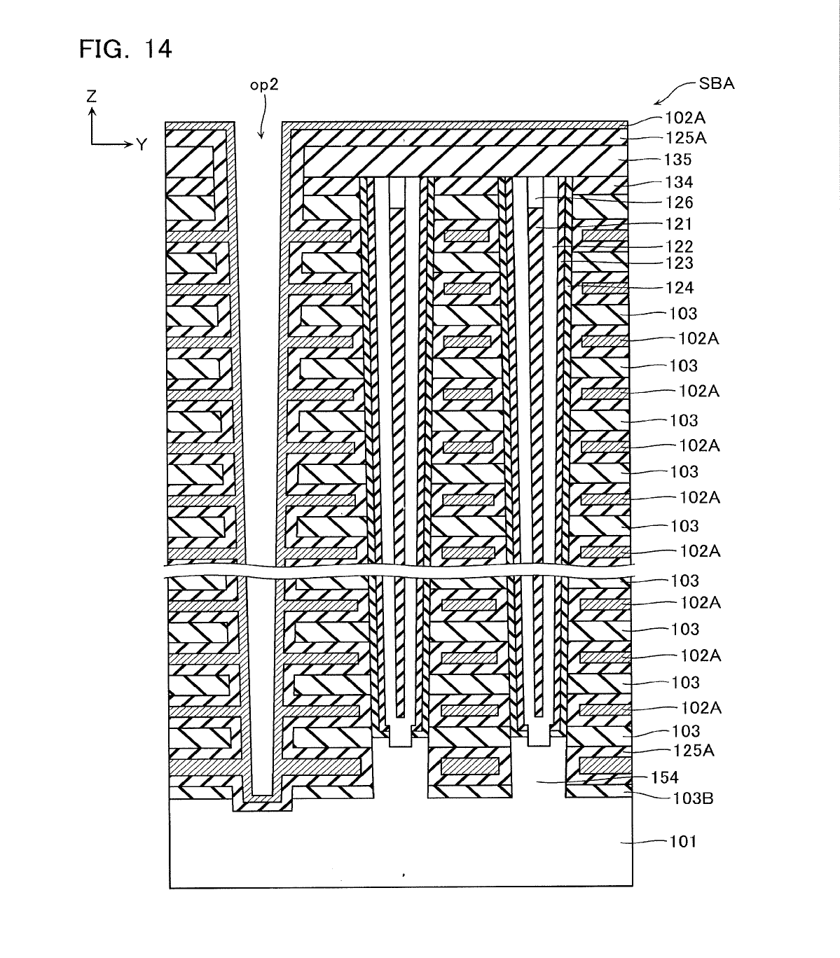

Then, as shown in FIG. 14, an insulating layer 125A and a conductive layer 102A are deposited along the inner wall of the trench op2 and the inner wall of the cavity which is generated by removing the sacrifice layers 141A and 141B using a CVD method. The insulating layer 125A is an insulating film that will be the block insulating layer 125 mentioned above. The conductive layers 102A are layers that will be the conductive layer 102 and 102B mentioned above. As described above, because the film thickness of the sacrifice layer 141B is larger than another one of the sacrifice layers 141A, a thickness of the conductive layer 102B is larger than another one of the conductive layers 102. Because the thickness of the sacrifice layer 141B is large, a thickness in the Z direction of a cavity generated by removing the sacrifice layer 141B is large. Therefore, the conductive layer 102B is easily embedded to the cavity, compared with the conductive layers 102 positioned at an upper layer thereof.

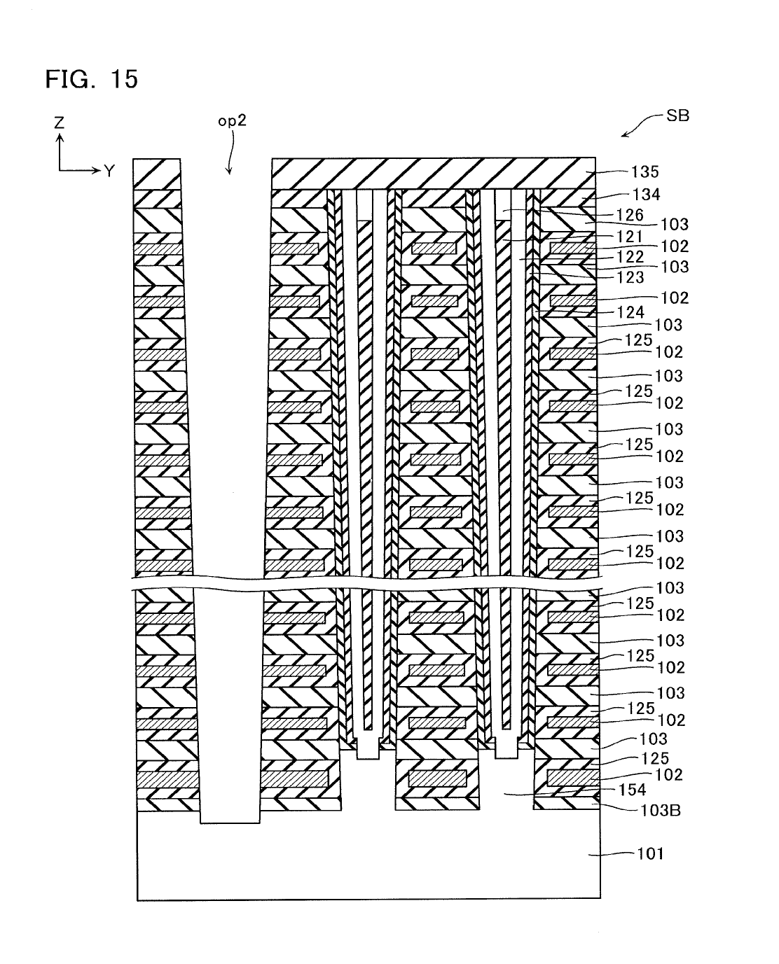

Next, as shown in FIG. 15, the insulating layer 125A and the conductive layer 102A formed on the upper surface of the insulating layer 135 and on the side wall of the trench op2 are removed by wet etching or the like. Hence, the conductive layer 102A does not short-circuit each other in the stacking direction, and the conductive layers 102 are formed. After that, an insulating layer 136 and a conductive layer 108 are embedded into the opening op2, and bit line contacts 137 are formed. Then, a structure illustrated in FIG. 5 will be completed.

### Second Embodiment

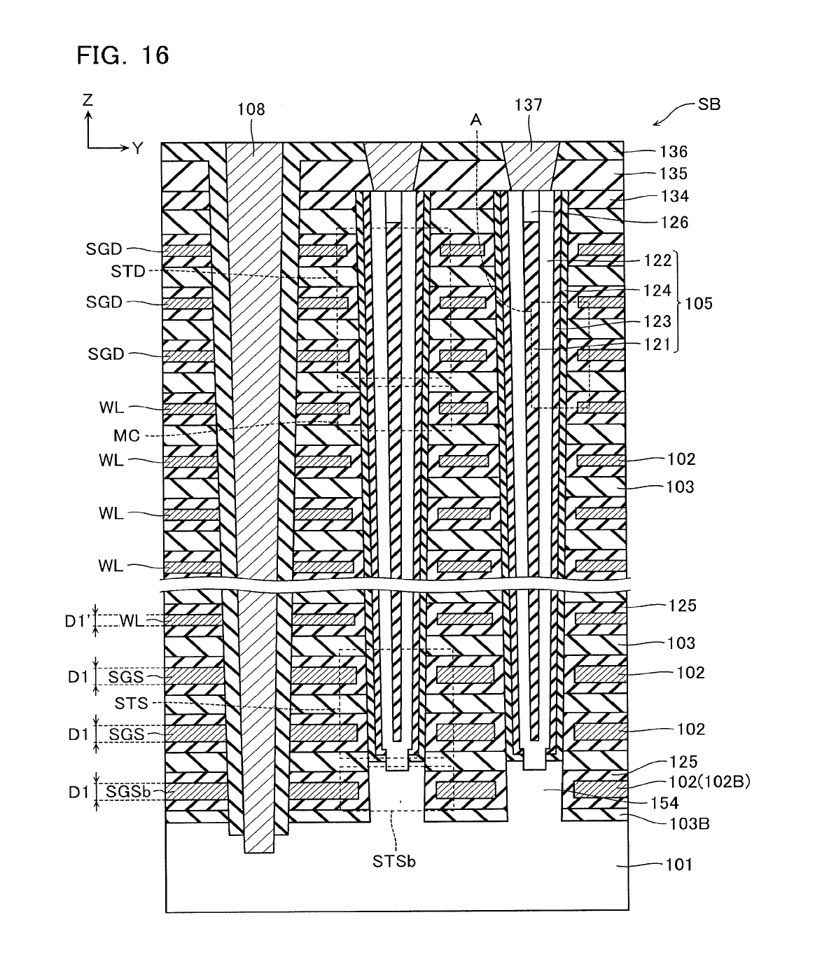

Next, with reference to FIG. 16, a structure of a nonvolatile semiconductor memory device according to a second embodiment will be described. A whole structure of the second embodiment (FIGS. 1 to 4) is similar to the first embodiment. Note that the second embodiment is different from the first embodiment in that not only the film thickness of the lowermost layer source side select gate line SGSb, but also the film thickness D1 in the Z direction of the conductive layer 102 as the source side select gate line SGS positioned at an upper layer of the lowermost layer source side select gate line SGSb is enlarged compared with film thicknesses D1′ of the conductive layers 102 configuring the word lines WL. The conductive layer 102 configuring the source side select gate line SGS is also easily damaged by a gas used in the CVD method for embedding the conductive layer or a gas emitted from the material itself because the conductive layer 102 configuring the source side select gate line SGS is also positioned at a lower layer compared with the conductive layers 102 configuring the word lines WL. Hence, an effect similar to the first embodiment can be obtained by enlarging the film thickness of the conductive layer 102 configuring the source side select gate line SGS compared with another one of the conductive layers positioned at an upper layer thereof.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, in the above embodiments, only the film thicknesses of the conductive layer 102B that functions as the lowermost layer source side select gate line SGSb and/or the conductive layer 102 that functions as the select gate line SGS positioned at the upper layer of the source side select gate line SGS are enlarged, but the prevent invention is not limited to this. For example, when the memory string MS includes a dummy memory cell, a film thickness of a conductive layer that functions as a dummy word line connected to the dummy memory cell may be enlarged compared with film thicknesses of the word lines WL of ordinary memory cells MC.

1. A semiconductor memory device, comprising:
a first semiconductor layer;
a stacked body including a plurality of conductive layers and a plurality of interlayer insulating layers stacked in a first direction above the first semiconductor layer;
a second semiconductor layer opposing the plurality of conductive layers, the second semiconductor layer having a longitudinal direction in the first direction; and
a memory insulating layer including a charge accumulation layer and positioned between the second semiconductor layer and the plurality of conductive layers,
the plurality of conductive layers including a first conductive layer as one of the plurality of conductive layers and a second conductive layer as another one of the plurality of conductive layers, the first conductive layer being adjacent to the first semiconductor layer via one of the plurality of interlayer insulating layers, and the second conductive layer being positioned between the first conductive layer and the plurality of conductive layers except the first and the second conductive layers,
a thickness in the first direction of the first conductive layer being larger than a thickness in the first direction of another one of the plurality of conductive layers except the first conductive layer and the second conductive layer, and
a thickness in the first direction of the second conductive layer being larger than the thickness of another one of the plurality of conductive layers except the first conductive layer and the second conductive layer.

2. The semiconductor memory device according to claim 1, wherein the one of the plurality of interlayer insulating layers positioned between the first semiconductor layer and the first conductive layer has a thickness in the first direction smaller than a thickness of another one of the plurality of interlayer insulating layers.

3. The semiconductor memory device according to claim 1, wherein
the plurality of conductive layers, the second semiconductor layer, and the memory insulating layer configure a memory unit, and
the first conductive layer is commonly connected to gates of first select transistors positioned at lower ends of a plurality of the memory units included in one memory block.

4. The semiconductor memory device according to claim 3, wherein the one of the plurality of interlayer insulating layers positioned between the first semiconductor layer and the first conductive layer has a thickness in the first direction smaller than a thickness of another one of the plurality of interlayer insulating layers.

5. (canceled)

6. The semiconductor memory device according to claim 1, wherein
the plurality of conductive layers, the second semiconductor layer, and the memory insulating layer configure a memory unit,
the first conductive layer is commonly connected to gates of first select transistors positioned at lower ends of a plurality of the memory units included in one memory block, and
the second conductive layer is commonly connected to gates of second select transistors, and the second select transistors are connected between one of the first select transistors and a memory transistor, respectively.

7. The semiconductor memory device according to claim 6, wherein the one of the plurality of interlayer insulating layers positioned between the first semiconductor layer and the first conductive layer has a thickness in the first direction smaller than a thickness of another one of the plurality of interlayer insulating layers.

8. The semiconductor memory device according to claim 1, further comprising:
a third semiconductor layer having an upper end connected to a lower end of the second semiconductor layer, the third semiconductor layer being epitaxially grown from the first semiconductor layer, and
a first interlayer insulating layer as one of the plurality of interlayer insulating layers positioned at an upper end in the first direction of the third semiconductor layer,
the first interlayer insulating layer having a thickness larger than a thickness of another one of the plurality of interlayer insulating layers.
